(19) United States
(12) Patent Application Publication
(10) Pub. No.: US 2006/0125379 A1
(43) Pub. Date: Jun. 15, 2006

(54) Phosphorescent organic optoelectronic structure

(75) Inventors: Tswen-Hsin Liu, Jhudong Township (TW); Chung-Wen Ko, Sijhih City (TW)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(73) Assignee: AU Optronics Corporation

(21) Appl. No.: 11/008,886

(22) Filed: Dec. 9, 2004

(51) Int. Cl. H01L 51/50; H05B 33/12

(52) U.S. Cl. 313/504; 257/102; 257/103; 257/101; 257/E51.026; 257/E51.018; 428/690; 428/917; 313/506; 427/66

(57) ABSTRACT

A phosphorescent organic light emitting device having a homogeneous structure for the blocking layer and emissive layer combination. The homogeneous structure comprises substantially a single material for both the blocking layer and the host material for the emissive layer. Alternatively, the blocking layer and the host material for the emissive layer are selected from one or more of BAlq, SAlq and PAlq. The homogenous structure is disposed between an electron source and a hole source. The electron source comprises an electron transport layer, an electron injection layer and cathode. The hole source comprises a hole transport layer, a hole injection layer and an anode. The emissive layer is doped with a guest phosphor dopant. Additionally, a buffer layer containing LiF and Al, or layers of CuPc, Al and LiF are disposed between the cathode and the electron transport layer.

### FIELD OF THE INVENTION

The present invention relates generally to an organic light emitting device and, more particularly, to a phosphorescent organic opto-electronic structure.

### BACKGROUND OF THE INVENTION

Most organic light emitting diodes contain an organic emissive layer that emits light by fluorescent luminescence. A fluorescent organic LED generally comprises an anode, a hole injection layer (HIL), a hole transport layer (HTL), an emissive layer (EML), an electron transport layer (ETL) and a cathode, as shown in FIG. 1. The EML, comprised of a host material doped with one or more fluorescent dyes, provides the function of light emission produced by excitons. The excitons are formed as a result of recombination of holes and electrons in the layer.

Raychaudhuri et al. (U.S. Pat. No. 6,551,725 B2) discloses an OLED wherein the hole injection layer is made of a porphorinic or phthalocyanine compound, the hole transport layer is made of various classes of aromatic amines, the emissive layer is comprised of a host material doped with one or more fluorescent dyes. According to Raychaudhuri et al., the preferred host materials include the class of 8-quinolinol metal chelate compounds with the chelating metals being Al, Mg, Li and Zn.

The excitons in a fluorescent emissive layer are in a singlet excited state and, therefore, only a small percentage of excitons result in fluorescent luminescence. Excitons in a phosphorescent medium are in an excited triplet state and, theoretically, all excitons can result in phosphorescent luminescence. In a phosphorescent OLED, holes from the hole transport layer recombine in the emissive layer with electrons from the electron transport layer to form triplet-based excitons. The triplet-based excitons diffuse over a relatively long distance in the emissive layer before emitting light it is possible that some of the excitons diffuse to the cathode and are quenched by the cathode, resulting in non-radiative exciton decay. Thus, it is advantageous and desirable to provide a hole blocking layer between the cathode and the emissive layer.

Adachi et al. (U.S. Pat. No. 6,645,645, hereafter referred to as Adachi I) discloses an organic light emitting device structure having an organic light emitting device (OLED) disposed over a substrate, wherein the OLED includes an anode, a hole transporting layer, a first electron transport layer doped with a phosphorescent material, a second electron transport layer, and a cathode. In particular, the emissive layer is comprised of an electron transporting host material having a triplet excited state energy level that is higher than the emissive triplet excited state energy level of the phosphorescent dopant.

Baldo et al. (U.S. Pat. No. 6,097,147) discloses another OLED having an anode, a hole transporting layer, an emission layer, a hole blocking layer (HBL), an electron transport layer and a cathode. The emission layer is made of a host material doped with a phosphorescent dopant. The host material for the emission layer is CBP and the dopant is 2,3,7,8,12,13,17,18-octaethyl-21H,23H-porphine platinum (II) (PtOEP). The hole blocking layer can be made of NPD, CBP, Alq₃ and bathocuproine (BCP), for example. But the choice of the blocking layer material depends on the materials of the emissive layer. According to Baldo et al., the blocking layer has a larger band gap than the energy level of the excitions formed in the emissive layer, which depends upon the material used in the emissive layer. For example, the blocking layer is made from BCP when the emissive layer is made from CBP doped with PtOEP.

Adachi et al. (“High-efficiency red electrophosphorescence device”, Appl. Phys. Lett., Vol. 78, No. 11, 12 Mar. 2001, pp. 1622-1624, hereafter referred to as Adachi II) discloses a phosphorescent OLED wherein the emissive layer consists of a conductive CBP host doped with a red phosphor bis(2-(2′-benzo[4,5-a]thienyl)pyridinato-N,C^{3′}) iridium(acetylacetonate) (Btp₂Ir(acac)) and the blocking layer is made from 2,9-dimethyl-4,7-diphenyl-phenanthroline.

Kwong et al. (High operational stability of electrophosphorescent devices”, Appl. Phys. Lett., Vol. 81, No. 1, 1 Jul. 2002, pp. 162-164) discloses a phosphorescent OLED wherein the emissive layer is made of CBP doped with Ir(ppy)₃ and the blocking layer is made from 2,2′,2″-(1,3,5-benzenetriyl)tris-[1-phenyl-1-H-benzimidazole (TPBi), aluminum (III)bis(2-methyl-8-quinolinato)triphenylsilanolate (SAlq), aluminum (III)bis(2-methyl-8-quinolinato)4-phenolate (PAlq) or aluminum (III)bis(2-methyl-8-quinolinato)4-phenylphenolate (BAlq).

In prior art phosphorescent OLEDs, the hole blocking layer and the emissive layer form a heterogeneous structure, such as BCP/CBP, BAlq/CBP, TPBi/CBP. Thus, a typical prior art phosphorescent OLED is shown in FIG. 2. This type of phosphorescent OLED using a heterogeneous structure for the blocking layer and emissive layer combination has been used in a passive display panel. However, the luminescence efficiency of the prior art phosphorescent OLEDs is not sufficiently high and the heterogeneous structure adds complexity to the manufacturing process.

It is thus advantageous and desirable to provide a method for improving the efficiency of a phosphorescent OLED and simplifying the manufacturing process.

### SUMMARY OF THE INVENTION

The phosphorescent organic light emitting device, according to the present invention, uses a homogeneous structure for the blocking layer and emissive layer combination. The homogeneous structure, according to the present invention, comprises substantially a single material for both the blocking layer and the host material for the emissive layer. Alternatively, the blocking layer and the host material for the emissive layer are derivatives of the same chemical compound. The homogenous structure is disposed between an electron source and a hole source.

Thus, the first aspect of the present invention is to provide a phosphorescent organic light emitting device. The device comprises:

an organic homogeneous structure comprising a host material containing at least a phosphorescent guest material;

an electron source for providing electrons to the homogeneous structure; and

a hole source for providing holes to the homogeneous structure so that at least some of the holes combine with electrons in the homogeneous structure to produce light via an excitation process, wherein the homogeneous structure is structured to reduce occurrence of the excitation process outside the homogeneous structure.

According to the present invention, the homogeneous structure comprises:

an emissive section substantially made of the host material containing the phosphorescent guest material, the emissive section disposed adjacent to the hole source; and

a blocking section made from a blocking material disposed adjacent to the electron source for reducing the occurrence of the excitation process outside the homogeneous structure, wherein the blocking material is substantially made from the host material.

According to the present invention, the host material is selected from the group consisting of BAlq, PAlq and SAlq.

According to the present invention, the emissive section has a first end adjacent to the hole source and a second end adjacent to the blocking section, wherein the phosphorescent guest material in the host material has a concentration with a spatial distribution such that the concentration is higher on the first end than the concentration on the second end. The emissive section comprises a layer of the host material containing the phosphorescent guest material, the layer disposed adjacent to the blocking section, and wherein the phosphorescent guest material in the layer has a substantially uniform concentration.

Alternatively, the emissive section comprises a layer of the host material containing the phosphorescent guest material, the layer having a first end adjacent to the hole source and a second end adjacent to the blocking section, and wherein the phosphorescent guest material in the layer has a concentration with a spatial distribution such that the concentration on the first end is higher than the concentration on the second end. The emissive section comprises at least a first layer and a second layer both made from the host material containing the phosphorescent guest material, the first layer disposed adjacent to the hole source and the second layer disposed adjacent to the blocking section, and wherein the phosphorescent guest material in the first layer has a higher concentration than the phosphorescent guest material in the second layer.

According to the present invention, the emissive section comprises a plurality of layers made from the host material containing the phosphorescent guest material, the layers disposed between the hole source and the blocking section, and the phosphorescent guest material in the host material has a higher concentration in the layer adjacent to the hole source than the concentration in the layer adjacent to the blocking section.

According to the present invention, the homogeneous structure comprises:

an emissive section substantially made from the host material containing the phosphorescent guest material, the emissive section disposed adjacent to the hole source; and

a blocking section made from a blocking material disposed adjacent to the electron source for reducing the occurrence of the excitation process outside the homogeneous structure, wherein-the blocking material and the host material are made from derivatives of a chemical compound. Each of the blocking material and the host material is selected from the group consisting of BAlq, SAlq and PAlq.

According to the present invention, the electron source comprises an electron transport layer and an electron injection layer.

According to the present invention, the device further comprises:

an anode disposed adjacent to the hole source; and

a cathode disposed adjacent to the electron transport layer, wherein the hole source comprises a hole transport layer disposed adjacent to the emissive layer, and a hole injection layer disposed between the hole transport layer and the anode. The device further comprises a layer substantially made from an alkaline halide, such as LiF, disposed between the cathode and the electron transport layer. The device further comprises a layer substantially made from CuPc disposed between the cathode and the electron transport layer.

Alternatively, the device further comprises a plurality of layers disposed between the cathode and the electron transport layer, said layers including:

a CuPc layer,

an aluminum layer, and

an LiF layer.

According to the present invention, the phosphorescent guest material comprises a dopant incorporated into the host material via a doping process.

The second aspect of the present invention provides an organic homogeneous structure for use in a phosphorescent organic light emitting device, the device comprising:

an electron source for providing electrons; and

a hole source for providing holes, the homogeneous structure disposed between the electron source and hole source so that at least some of holes combine with the electrons in the homogeneous structure to produce light via an excitation process. The homogeneous structure comprises:

an emissive section made from a host material containing at least a phosphorescent guest material, the emissive section disposed adjacent to the hole source, and

a blocking section adjacent to the electron source for reducing occurrence of the excitation process outside the homogeneous structure.

According to the present invention, the blocking material is substantially made from the host material, and the host material is selected from the group consisting of BAlq, PAlq and SAlq.

According to the present invention, the emissive section has a first end adjacent to the hole source and a second end adjacent to the blocking section, wherein the phosphorescent guest material in the host material has a concentration with a spatial distribution such that the concentration is higher on the first end than the concentration on the second end. The emissive section comprises a layer of the host material containing the phosphorescent guest material, the layer disposed adjacent to the blocking section, and wherein the phosphorescent guest material in the layer has a substantially uniform concentration.

Alternatively, the emissive section comprises a layer of the host material containing the phosphorescent guest material, the layer having a first end adjacent to the hole source and a second end adjacent to the blocking section, and wherein the phosphorescent guest material in the layer has a concentration with a spatial distribution such that the concentration on the first end is higher than the concentration on the second end. The emissive section comprises a plurality of layers made from the host material containing the phosphorescent host material, the layers disposed between the hole source and the blocking section, and the phosphorescent guest material in the host material has a higher concentration in the layer adjacent to the hole source than the concentration in the layer adjacent to the blocking section. The blocking section is made from a blocking material, and wherein the blocking material and the host material are made from derivatives of a chemical compound, such as BAlq, SAlq and PAlq.

The third aspect of the present invention provides a method to improve operational efficiency of a phosphorescent organic light emitting device comprising an emissive section made from a host material containing a phosphorescent guest material, an electron source for providing electrons to the emissive section, and a hole source for providing holes to the emissive section so that at least some of the holes combine with the electrons in the emissive section to produce light in an excitation process, said method comprising:

providing a blocking section between the emissive section and the electron source so as to reduce occurrence of said excitation process outside of the emissive section, where the blocking section and the emissive section form a homogeneous structure.

According to the present invention, the blocking section is made from a blocking material substantially the same as the host material or different from that of the host material. Each of the host material and the blocking material is selected from the group consisting of BAlq, SAlq and PAlq.

The present invention will become apparent upon reading the description taken in conjunction with FIGS. 3 to 8c.

### BRIEF DESCRIPTION OF THE DRAWINGS

FIG. 1 is a schematic representation illustrating a prior art fluorescent organic light emitting diode.

FIG. 2 is a schematic representation illustrating a prior art phosphorescent organic light emitting diode.

FIG. 3a is a schematic representation illustrating an embodiment of the phosphorescent organic light emitting diode, according to the present invention.

FIG. 3b is a schematic representation illustrating another embodiment of the phosphorescent organic light emitting diode, according to the present invention.

FIG. 4 is a block diagram showing a general representation of the phosphorescent organic light emitting diode, according to the present invention.

FIG. 5a is a schematic representation showing an embodiment of the homogeneous structure, according to the present invention.

FIG. 5b is a schematic representation showing the preferred embodiment of the homogeneous structure, according to the present invention.

FIG. 5c is a schematic representation showing another embodiment of the homogeneous structure, according to the present invention.

FIG. 5d is a schematic representation showing yet another embodiment of the homogeneous structure, according to the present invention.

FIG. 6a is a plot showing the dopant concentration in the homogeneous structure of FIG. 5a.

FIG. 6b is a plot showing the dopant concentration in the homogeneous structure of FIG. 5b.

FIG. 6c is a plot showing the dopant concentration in the homogeneous structure of FIG. 5c.

FIG. 6d is a plot showing the dopant concentration in the homogeneous structure of FIG. 5d

FIG. 7 is a schematic representation showing a specimen of a phosphorescent organic light emitting diode having a heterogeneous structure for use in an experiment.

FIG. 8a is a schematic representation showing a specimen of a phosphorescent organic light emitting diode having a homogeneous structure for use in the experiment.

FIG. 8b is a schematic representation showing a specimen of a phosphorescent organic light emitting diode having a different homogeneous structure for use in the experiment.

FIG. 8c is a schematic representation showing a specimen of a phosphorescent organic light emitting diode having a heterogeneous structure and a light reflector for use in the experiment.

FIG. 9a is a plot of luminance yield v. current density.

FIG. 9b is a plot of power efficiency v. brightness.

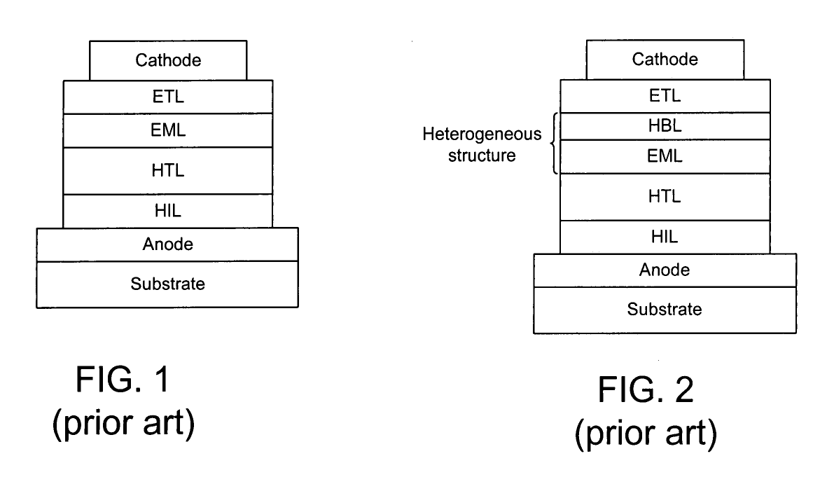

### DETAILED DESCRIPTION OF THE INVENTION

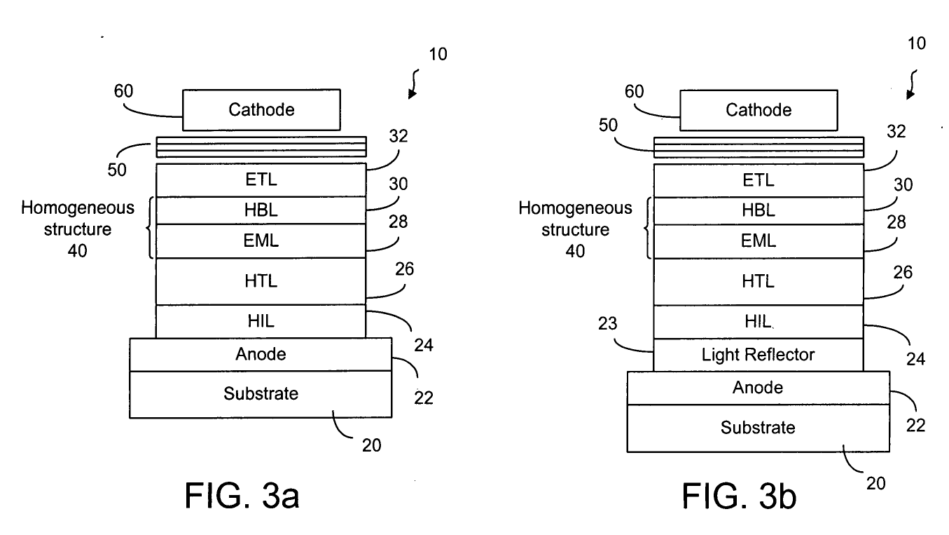

The present invention uses a homogeneous structure for the hole blocking layer (HBL)/emissive layer (EML) combination. As shown in FIG. 3a, the phosphorescent OLED 10, according to one embodiment of the present invention, comprises: a substrate 20, an anode 22, a hole injection layer (HIL) 24, a hole transport layer (HTL) 26, a homogeneous structure 40, an electron transport layer 32 and a cathode 60. Optionally, one or more buffer layers 50 are provided between the ETL 32 and the cathode 60. The homogeneous structure 40 comprises an emissive layer (EML) 28 and a hole blocking layer 30.

The materials for the substrate 20, the anode 22, the HIL 24, the HTL 26, the ETL 32 and the cathode 60 are known in the art. These materials have been disclosed in Raychaudhuri et al., Adachi I, Adachi II, and Kwong et al., for example. These references are incorporated in their entirety herein by reference. The buffer layers 50 may contain Al, LiF and CuPc.

In another embodiment of the present invention, as shown in FIG. 3b, the phosphorescent OLED 10 further comprises a light reflection layer 23 between the HIL 24 and the substrate 20. The light reflection layer 23 can be made of Ag, for example.

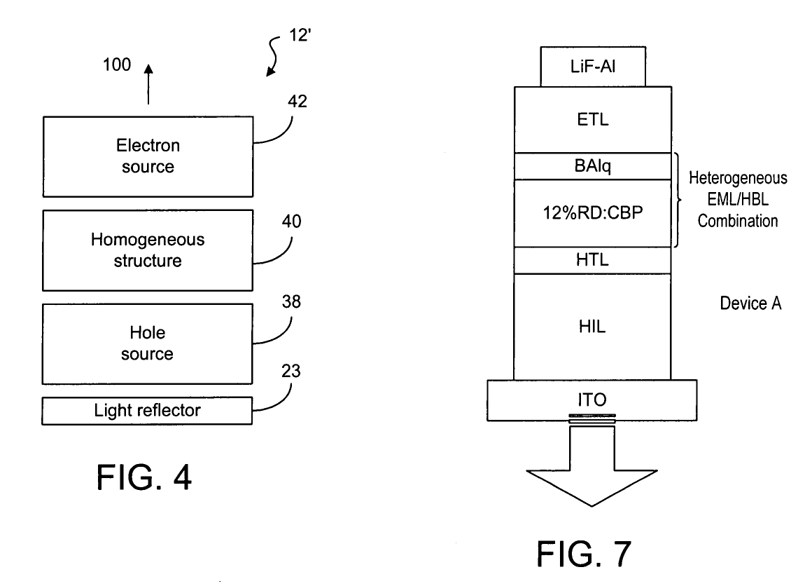

Thus, in general, the phosphorescent OLED, according to the present invention, can be represented by a device structure 12′ as shown in FIG. 4. As shown in FIG. 4, the device structure 12′ comprises a homogeneous emissive/blocking structure 40 containing a phosphorescent guest dopant, a hole source 38 and an electron source 42 to provide holes and electrons, respectively, to the homogeneous structure 40. Through the combination of holes and electrons in the homogeneous structure 40, light 100 is produced and emitted out of the device structure 12′. Optionally, a light reflection layer 23 is disposed on the hole source side. The hole source 38 may comprise an anode, a hole injection layer, and a hole transport layer. The electron source 42 may comprise an electron transport layer and a cathode, which is also considered as an electron injection layer. The electron source 42 may also comprise one or more buffer layers made from materials such as CuPc, Al and LiF.

In the homogeneous structure 40, according to the present invention, the emissive layer 28 and the hole blocking layer 30 are made of substantially the same material. For example, the hole blocking layer 30 is made from BAlq and the emissive layer 28 is made from BAlq doped with one or more guest phosphors. The guest phosphors used in doping the host material depend on the desirable color of the phosphorescent OLED. For example, phosphorescent organometallic iridium complexes, such as Ir(ppy)₃ and (ppy)₂ Ir(acac), give strong green emission. For blue emission, organometallic complexes such as trivalent metal quinolate complexes, Schiff base divalent metal complexes, metal acetylacetonate complexes, metal bidentate ligand complexes, bisphosphonates, metal maleontriledithiolate complexes, molecular charge transfer complexes, aromatic and heterocyclic polymers and rare earth mixed chelates, can be used. For red emission, red dopants such as 2,3,7,8,12,13,17,18-octaethyl-21H,23H-porphine platinum (II) (PtOEP) and Btp₂Ir(acac) can be used. However, the choice of guest dopants to be incorporated into a host material in the emissive layer is not part of the present invention. Other materials suitable for use for both HBL and EML in the same homogeneous structure include SAlq, PAlq, TBPi, and BCP.

Alternatively, the homogeneous layer 40, according to the present invention, can be made of two derivatives of the same chemical compound. For example, the HBL/EML combination can be a BAlq/SAlq combination, a SAlq/PAlq combination or any combination from two of the derivatives BAlq, SAlq and PAlq.

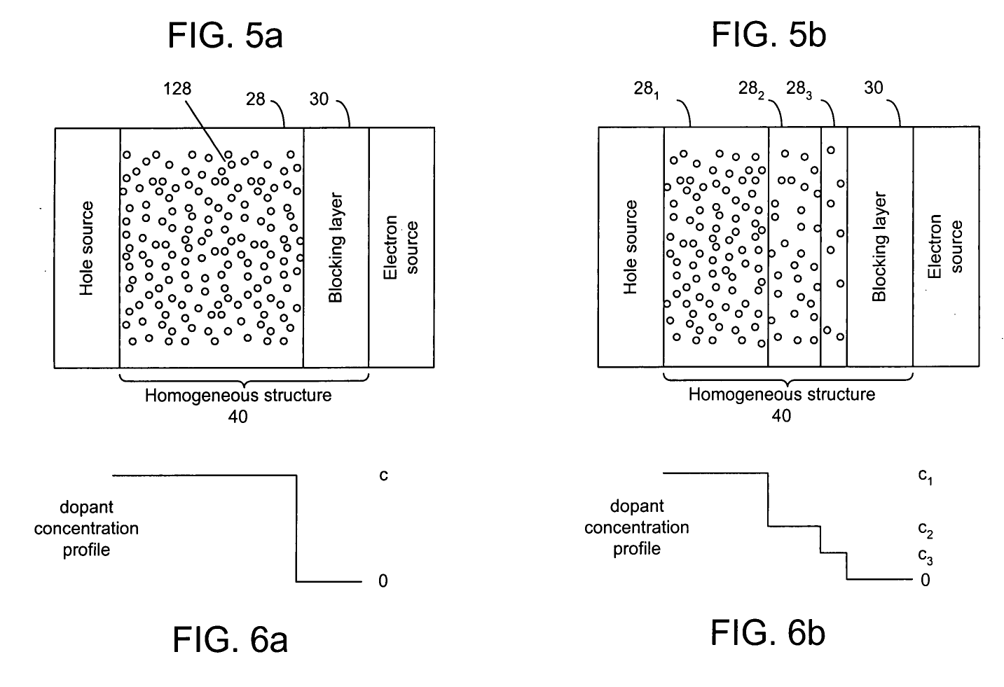

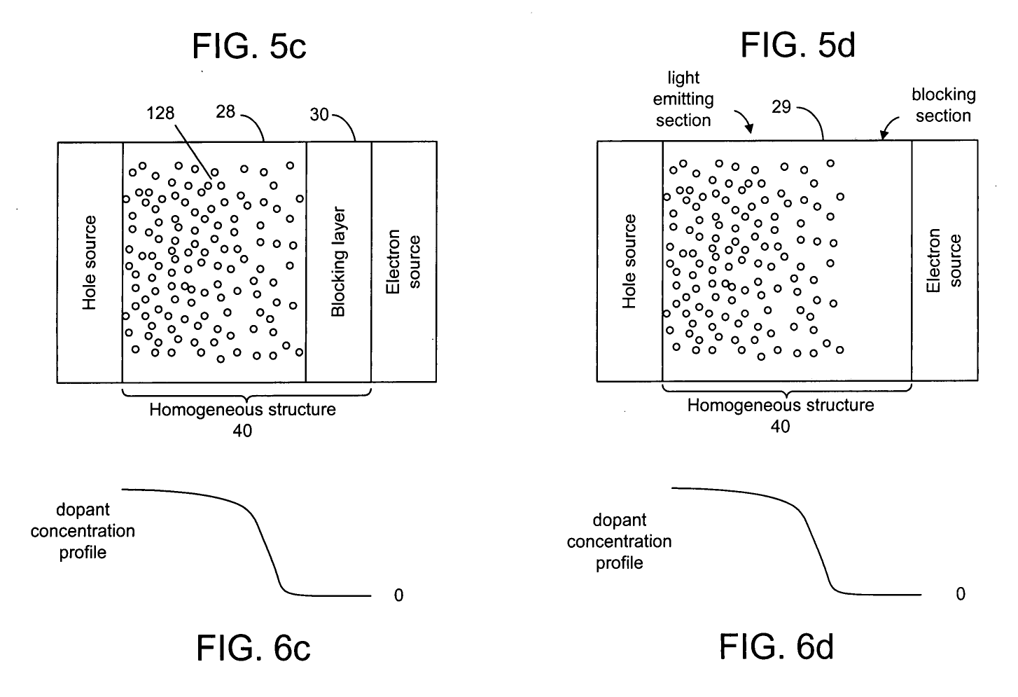

FIG. 5a illustrates one of the simplest homogeneous structures, according to the present invention. As shown in FIG. 5a, the homogeneous structure 40 comprises a blocking layer 30 and an EML 28 doped with guest phosphor dopant 128. The dopant concentration in such a homogeneous structure is shown in FIG. 6a. Preferably, the homogeneous structure 40 comprises a blocking layer 30 and a plurality of emissive sub-layers 281, 282, . . . , 28n as shown in FIG. 5b (only three sub-layers are shown). The dopant concentrations c₁, c₂, . . . , cₙ, in the sub-layers 28₁, 28₂, . . . , 28ₙ are different and in a decreasing order. The dopant concentration profile for such a homogeneous structure is shown in FIG. 6b.

It is possible to provide an emissive layer 28 having a gradient dopant concentration profile as shown in FIGS. 5c and 6c. It is also possible to provide a homogeneous structure comprising a block layer 29 wherein the dopant is incorporated only in one section (the light emission section) of the layer and becomes diminished at a certain depth so that the remaining section (the blocking section) of the layer effectively does not contain the guest dopant, as shown in FIGS. 5d and 6d.

In order to show the improved luminescent efficiency of the phosphorescent OLED having a homogeneous structure, four experimental specimens have been made. A specimen of a phosphorescent OLED having a heterogeneous structure is shown in FIG. 7. This specimen (Device A) contains an ITO anode, an HIL, an HTL, a heterogeneous structure consisting of an emissive layer made from CBP doped with 12% red phosphor dopant and a block layer made from BAlq, an ETL and a cathode-buffer layer containing LiF and Al.

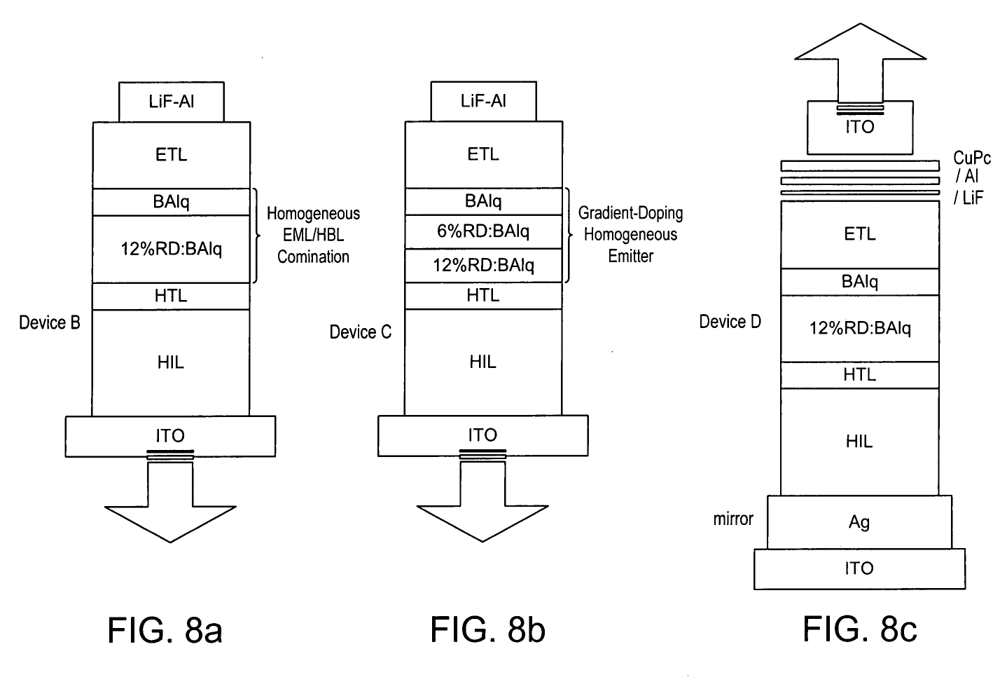

A first specimen of a phosphorescent OLED having a homogeneous structure is shown in FIG. 8a. Instead of the heterogeneous structure as shown in FIG. 7, the phosphorescent OLED in FIG. 8a (Device B) has a homogeneous structure comprising a blocking layer made from BAlq and an emissive layer made from BAlq doped with 12% red phosphor dopant.

A second specimen of the phosphorescent OLED having a homogeneous structure is shown in FIG. 8b (Device C). The homogeneous structure comprises a first emissive sub-layer made from BAlq with 12% red phosphor dopant, a second emissive sub-layer made from BAlq with 6% red phosphor dopant, and a blocking layer of substantially non-doped BAlq.

A third specimen of the phosphorescent OLED having a homogeneous structure is shown in FIG. 8c (Device D). This specimen is structurally similar to the specimen as shown in FIG. 8a. However, in addition to all the layers in the first specimen, a light reflection layer is disposed between the anode and the HIL, and a plurality of buffer layers are disposed between the ETL and an ITO anode.

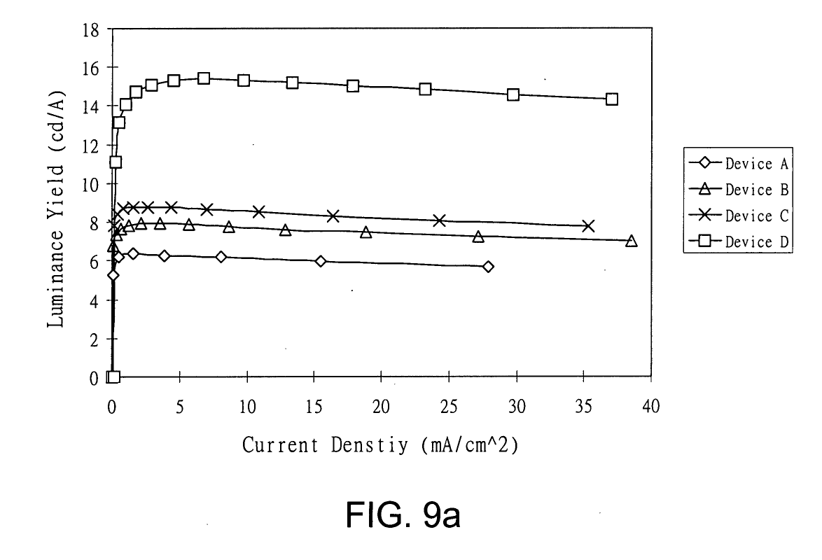

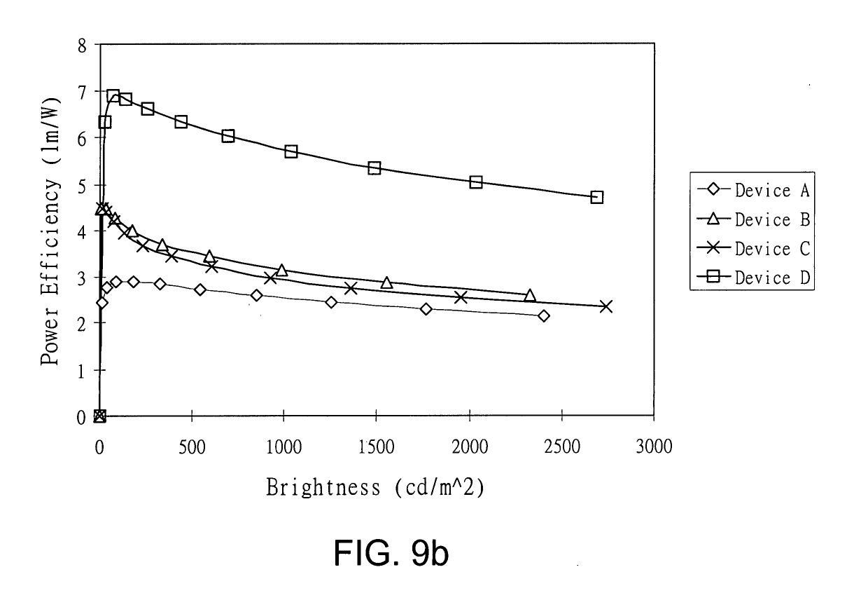

The experimental results are shown in FIGS. 9a and 9b. FIG. 9a is a plot of luminance yield versus current density. FIG. 9b is a plot of power efficiency versus brightness. As can be seen from FIGS. 9a and 9b. Both the luminance yield and the power efficiency of the phosphorescent OLEDs with a homogeneous structure are higher than the phosphorescent OLED with a heterogeneous structure. While the efficiency of the emissive layer with gradient doping is higher than the emissive layer with uniform doping, the use of a reflection layer and a plurality of buffer layers significantly improves the efficiency of a phosphorescent OLED.

What is claimed is:

1. A phosphorescent organic light emitting device, comprising:
an organic homogeneous structure comprising a host material containing at least a phosphorescent guest material;
an electron source for providing electrons to the homogeneous structure; and
a hole source for providing holes to the homogeneous structure so that at least some of the holes combine with electrons in the homogeneous structure to produce light via an excitation process, wherein the homogeneous structure is structured to reduce occurrence of the excitation process outside the homogeneous structure.

2. The device of claim 1, wherein the homogeneous structure comprises:
an emissive section substantially made of the host material containing the phosphorescent guest material, the emissive section disposed adjacent to the hole source; and
a blocking section made from a blocking material disposed adjacent to the electron source for reducing the occurrence of the excitation process outside the homogeneous structure, wherein the blocking material is substantially made from the host material.

3. The device of claim 2, wherein the host material is selected from the group consisting of BAlq, PAlq and SAlq.

4. The device of claim 3, wherein the emissive section has a first end adjacent to the hole source and a second end adjacent to the blocking section, wherein the phosphorescent guest material in the host material has a concentration with a spatial distribution such that the concentration is higher on the first end than the concentration on the second end.

5. The device of claim 3, wherein the emissive section comprises a layer of the host material containing the phosphorescent guest material, the layer disposed adjacent to the blocking section, and wherein the phosphorescent guest material in the layer has a substantially uniform concentration.

6. The device of claim 3, wherein the emissive section comprises a layer of the host material containing the phosphorescent guest material, the layer having a first end adjacent to the hole source and a second end adjacent to the blocking section, and wherein the phosphorescent guest material in the layer has a concentration with a spatial distribution such that the concentration on the first end is higher than the concentration on the second end.

7. The device of claim 3, wherein the emissive section comprises at least a first layer and a second layer both made from the host material containing the phosphorescent guest material, the first layer disposed adjacent to the hole source and the second layer disposed adjacent to the blocking section, and wherein the phosphorescent guest material in the first layer has a higher concentration than the phosphorescent guest material in the second layer.

8. The device of claim 3, wherein the emissive section comprises a plurality of layers made from the host material containing the phosphorescent guest material, the layers disposed between the hole source and the blocking section, and the phosphorescent guest material in the host material has a higher concentration in the layer adjacent to the hole source than the concentration in the layer adjacent to the blocking section.

9. The device of claim 1, wherein the homogeneous structure comprises:
an emissive section substantially made from the host material containing the phosphorescent guest material, the emissive section disposed adjacent to the hole source; and
a blocking section made from a blocking material disposed adjacent to the electron source for reducing the occurrence of the excitation process outside the homogeneous structure, wherein the blocking material and the host material are made from derivatives of a chemical compound.

10. The device of claim 9, wherein each of the blocking material and the host material is selected from the group consisting of BAlq, SAlq and PAlq.

11. The device of claim 2, wherein the electron source comprises an electron transport layer and an electron injection layer.

12. The device of claim 11, further comprising:
an anode disposed adjacent to the hole source; and
a cathode disposed adjacent to the electron transport layer, wherein the hole source comprises a hole transport layer disposed adjacent to the emissive layer, and a hole injection layer disposed between the hole transport layer and the anode.

13. The device of claim 12, further comprising a layer substantially made from an alkaline halide disposed between the cathode and the electron transport layer.

14. The device of claim 12, further comprising a layer substantially made from LiF disposed between the cathode and the electron transport layer.

15. The device of claim 12, further comprising a layer substantially made from CuPc disposed between the cathode and the electron transport layer.

16. The device of claim 12, further comprising a plurality of layers disposed between the cathode and the electron transport layer, said layers including:
a CuPc layer,
an aluminum layer, and
an LiF layer.

17. The device of claim 1, wherein the phosphorescent guest material comprises a dopant incorporated into the host material via a doping process.

18. An organic homogeneous structure for use in a phosphorescent organic light emitting device, the device comprising:
an electron source for providing electrons; and
a hole source for providing holes, the homogeneous structure disposed between the electron source and hole source so that at least some of holes combine with the electrons in the homogeneous structure to produce light via an excitation process, the homogeneous structure comprising:
an emissive section made from a host material containing at least a phosphorescent guest material, the emissive section disposed adjacent to the hole source, and
a blocking section adjacent to the electron source for reducing occurrence of the excitation process outside the homogeneous structure.

19. The homogeneous structure of claim 18, wherein the blocking material is substantially made from the host material.

20. The homogeneous structure of claim 18, wherein the host material is selected from the group consisting of BAlq, PAlq and SAlq.

21. The homogeneous structure of claim 20, wherein the emissive section has a first end adjacent to the hole source and a second end adjacent to the blocking section, wherein the phosphorescent guest material in the host material has a concentration with a spatial distribution such that the concentration is higher on the first end than the concentration on the second end.

22. The homogeneous structure of claim 20, wherein the emissive section comprises a layer of the host material containing the phosphorescent guest material, the layer disposed adjacent to the blocking section, and wherein the phosphorescent guest material in the layer has a substantially uniform concentration.

23. The homogeneous structure of claim 20, wherein the emissive section comprises a layer of the host material containing the phosphorescent guest material, the layer having a first end adjacent to the hole source and a second end adjacent to the blocking section, and wherein the phosphorescent guest material in the layer has a concentration with a spatial distribution such that the concentration on the first end is higher than the concentration on the second end.

24. The homogeneous structure of claim 20, wherein the emissive section comprises a plurality of layers made from the host material containing the phosphorescent host material, the layers disposed between the hole source and the blocking section, and the phosphorescent guest material in the host material has a higher concentration in the layer adjacent to the hole source than the concentration in the layer adjacent to the blocking section.

25. The homogeneous structure of claim 18, wherein the blocking section is made from a blocking material, and wherein the blocking material and the host material are made from derivatives of a chemical compound.

26. The homogeneous structure of claim 25, wherein each of the blocking material and the host material is selected from the group consisting of BAlq, SAlq and PAlq.

27. A method to improve operational efficiency of a phosphorescent organic light emitting device comprising an emissive section made from a host material containing a phosphorescent guest material, an electron source for providing electrons to the emissive section, and a hole source for providing holes to the emissive section so that at least some of the holes combine with the electrons in the emissive section to produce light in an excitation process, said method comprising:
providing a blocking section between the emissive section and the electron source so as to reduce occurrence of said excitation process outside of the emissive section, where the blocking section and the emissive section form a homogeneous structure.

28. The method of claim 27, wherein the blocking section is made from a blocking material substantially the same as the host material.

29. The method of claim 28, wherein the host material is selected from the group consisting of BAlq, SAlq and PAlq.

30. The method of claim 27, wherein the blocking section is made from a blocking material, and wherein the blocking material and the host material are made from derivatives of a chemical compound.

31. The method of claim 30, wherein each of the blocking material and the host material is selected from the group consisting of BAlq, SAlq and PAlq.
